(19) United States
(12) Patent Application Publication
(10) Pub. No.: US 2025/0300014 A1
(43) Pub. Date: Sep. 25, 2025

(54) MANUFACTURING METHOD OF SEMICONDUCTOR DEVICE

(71) Applicant: NANYA TECHNOLOGY CORPORATION, New Taipei city (TW)

(72) Inventors: De-You SUN, New Taipei City (TW); Kuan Han CHEN, New Taipei City (TW)

(21) Appl. No.: 18/613,835

(22) Filed: Mar. 22, 2024

(51) Int. Cl. H01L 21/768; H01L 21/3213

(52) U.S. Cl. CPC H01L 21/76877; H01L 21/32135; H01L 21/76819; H01L 21/76834

(57) ABSTRACT

In accordance with an aspect of the present disclosure, a manufacturing method of a semiconductor device is provided. The method include following steps. A semiconductor structure is provided, wherein the semiconductor structure includes a substrate, and a trench in the substrate. A conductive material is deposited to fill the trench. A first etching process is performed to etch back a portion the conductive material such that a top surface of the conductive material is a V-shape surface. A sacrificial film is deposited on the top surface of the conductive material, wherein the sacrificial film includes fluorine. A second etching process is performed to form a bottom conductive layer in the trench, wherein the sacrificial film is removed such that a top surface of the bottom conductive layer is a flat surface. A top conductive layer is formed on the on the bottom conductive layer.

### BACKGROUND

### Field of Invention

The present invention relates to a manufacturing method of semiconductor device. More particularly, the present invention relates to an etching back process may improve the V-shape issue in the bottom conductive layer.

### Description of Related Art

In recent decades, demand to storage capability has increased as electronic products continue to improve. In order to increase storage capability of a memory device (e.g., a DRAM device), more memory cells are integrated in the memory device. As the integration level increases, fabrication process of the memory device become much more complicated, and process window become rather narrow. As the process window becoming narrower, V-shaped interface problems often occur in the bottom conductive layer. The tip structure in the V-shaped interface can easily cause tip discharge, thereby causing the electrical properties of the word lines.

Accordingly, the present disclosure provides manufacturing method of semiconductor device, wherein the V-shape issue in the bottom conductive layer may be improved.

### SUMMARY

In accordance with an aspect of the present disclosure, a manufacturing method of a semiconductor device is provided. The method include following steps. A semiconductor structure is provided, wherein the semiconductor structure includes a substrate, and a trench in the substrate. A conductive material is deposited to fill the trench. A first etching process is performed to etch back a portion the conductive material such that a top surface of the conductive material is a V-shape surface. A sacrificial film is deposited on the top surface of the conductive material, wherein the sacrificial film includes fluorine. A second etching process is performed to form a bottom conductive layer in the trench, wherein the sacrificial film is removed such that a top surface of the bottom conductive layer is a flat surface. A top conductive layer is formed on the bottom conductive layer.

According to some embodiments of the present disclosure, wherein the semiconductor structure further comprises: a lining layer disposed on a sidewall of the trench.

According to some embodiments of the present disclosure, wherein a precursor for forming the sacrificial film comprises nitrogen trifluoride (NF₃).

According to some embodiments of the present disclosure, wherein the sacrificial film comprises titanium tetrafluoride (TiF₄).

According to some embodiments of the present disclosure, further including: depositing a cap material to fill the trench and above the substrate; and removing a portion of the cap material to form a capping layer on the top conductive layer.

According to some embodiments of the present disclosure, wherein removing the portion of the cap material comprises performing a planarization process.

According to some embodiments of the present disclosure, wherein the first etching process and the second etching process are gas etching process.

According to some embodiments of the present disclosure, wherein an etchant used in the first etching process and the second etching process includes chlorine.

According to some embodiments of the present disclosure, wherein an etchant used in the first etching process and the second etching process includes fluorine.

According to some embodiments of the present disclosure, wherein the first etching process and the second etching process are performed at a temperature of 115° C. to 120° C.

According to some embodiments of the present disclosure, wherein the conductive material is titanium nitride.

In accordance with an aspect of the present disclosure, a manufacturing method of a semiconductor device is provided. The method include following steps. An active region is formed in a substrate. A trench is formed in the active region. A lining layer is deposited in the trench. A conductive material deposited to fill the trench. A first etching process is performed to etch back a portion of the conductive material such that a center portion of a top surface of the conductive material is lower than a peripheral portion of the top surface of the conductive material. A sacrificial film is deposited on the top surface of the conductive material, wherein the sacrificial film includes fluorine. A second etching process is performed to form a bottom conductive layer in the trench, wherein the sacrificial film is removed such that a center portion of a top surface of the bottom conductive layer is coplanar with a peripheral portion of the top surface of the bottom conductive layer. A top conductive layer is formed on the bottom conductive layer.

According to some embodiments of the present disclosure, wherein a precursor for forming the sacrificial film comprises nitrogen trifluoride (NF₃).

According to some embodiments of the present disclosure, wherein the sacrificial film comprises titanium tetrafluoride (TiF₄).

According to some embodiments of the present disclosure, further including: depositing a cap material to fill the trench and above the substrate; and removing a portion of the cap material to form a capping layer on the top conductive layer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view schematic diagram of a semiconductor device, in accordance with some embodiments;

FIG. 2 is a cross-sectional view schematic diagram of a semiconductor device after forming a bottom conductive material, in accordance with some embodiments;

FIG. 3 is a cross-sectional view schematic diagram a semiconductor device after removing a portion of bottom conductive material, in accordance with some embodiments;

FIG. 4 is a cross-sectional view schematic diagram of a semiconductor device after forming a sacrificial film on the bottom conductive material, in accordance with some embodiments;

FIG. 5 is a cross-sectional view schematic diagram of a semiconductor device after removing the sacrificial film to form a bottom conductive layer, in accordance with some embodiments;

FIG. 6 is a cross-sectional view schematic diagram of a semiconductor device after forming a top conductive layer, in accordance with some embodiments; and

FIG. 7 is a cross-sectional view schematic diagram of a semiconductor device after forming a capping layer, in accordance with some embodiments.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

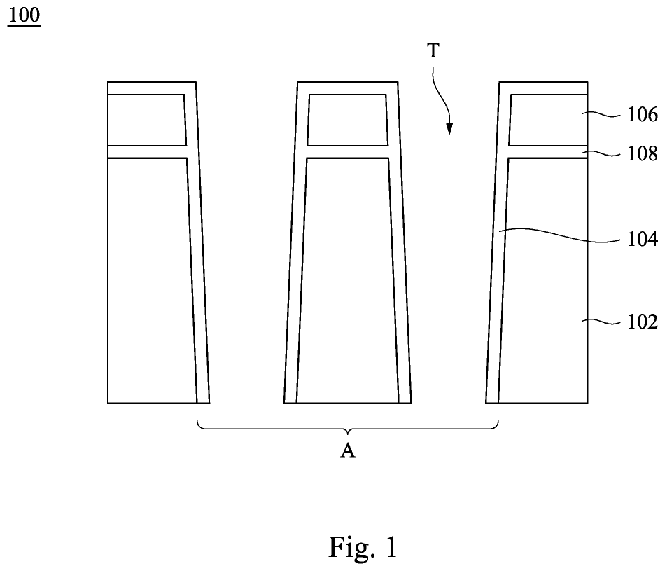

FIG. 1 is cross-sectional view schematic diagram a semiconductor device 100, in accordance with some embodiments. The semiconductor device 100 can be applied in an integrated circuit (IC) or a part thereof, such as a logic circuit, a resistor, a capacitor, an inductor, a memory (such as a dynamic random access memory (DRAM)), and the like. It should be understood that some elements of the semiconductor device 100 are not shown in FIGS. 1-7 to simplify the drawings, and that additional elements may be included in other embodiments of the semiconductor device 100.

Referring to FIG. 1, the semiconductor device 100 includes a substrate 102 and a trench T in the substrate 102. The trench located in an active region A in the substrate 102. The semiconductor device 100 may include a lining layer 104 disposed on a sidewall of the trench T. The semiconductor device 100 may include a cover layer 106 disposed on a top surface of the substrate 102. The semiconductor device 100 may include an oxide layer 108.

In some embodiments, the substrate 102 may be a semiconductor substrate, such as a bulk semiconductor substrate, a semiconductor-on-insulator (SOI) substrate, etc., wherein the insulator may be a buried oxide (BOX) layer, a silicon oxide layer, or the like. In some embodiments, the substrate 102 can be doped (eg, containing p-type or n-type dopants) or undoped. In some embodiments, the semiconductor material of the substrate 102 may include silicon, germanium, compound semiconductors (including silicon carbide, gallium arsenide, gallium phosphide, indium phosphide, indium arsenide, and/or indium antimonide), alloy semiconductors or a combination thereof. The substrate 102 can also be formed of other materials, such as sapphire, indium tin oxide, and the like.

In some embodiments, the lining layer 104 may include oxide and is formed by suitable deposition process such that the lining layer 104 is conformally formed on sidewall of the trench T. In some embodiments, the cover layer 106 may include nitride and is formed by suitable deposition process. In some embodiments, the oxide layer 108 and the lining layer 104 may include same material. For example, the lining layer 104, the cover layer 106, and the oxide layer 108 is formed by chemical vapor deposition (CVD), atomic layer deposition (ALD), or physical vapor deposition (PVD).

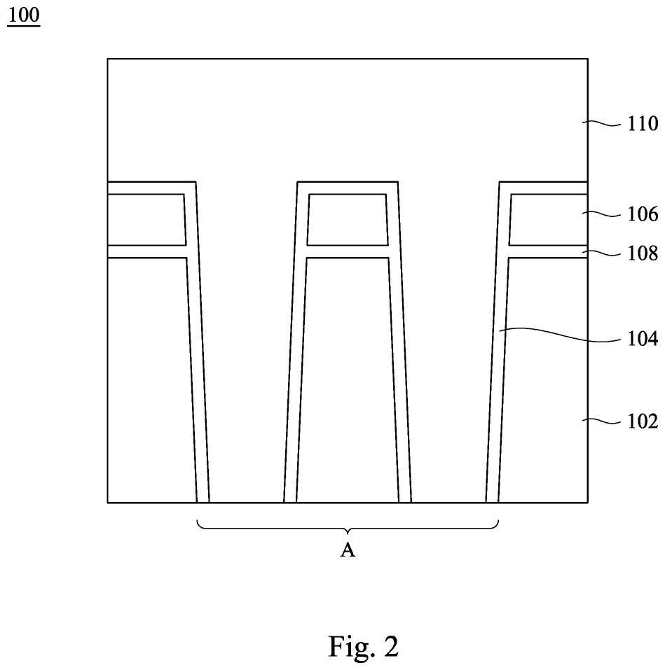

Referring to FIG. 2, a conductive material 110 is deposited to fill the trench T. In some embodiments, the conductive material 110 may be form on the cover layer 106. For example, the conductive material 110 is formed by chemical vapor deposition (CVD), atomic layer deposition (ALD), or physical vapor deposition (PVD). In some embodiments, the conductive material 110 may include titanium nitride (TiN).

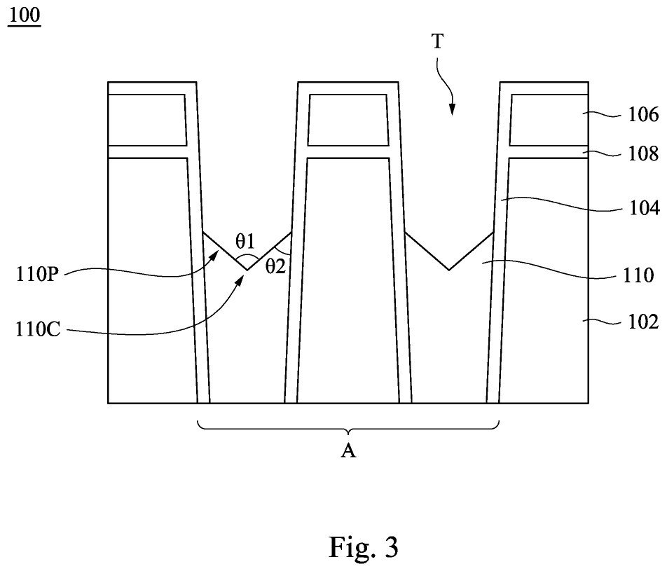

Referring to FIG. 3, performing a first etching process to etch back a portion the conductive material 110. In some embodiments, the first etching process is a gas etching process. In some embodiments, the first gas etchant includes fluorine and chlorine. In some embodiments, the first etching process is performed at a temperature of 115° C. to 120° C. After the first etching process, a top surface of the conductive material is a V-shape surface. In other words, a center portion 110C of a top surface of the conductive material 110 is lower than a peripheral portion 110P of the top surface of the conductive material 110. The peripheral portion 110P of the conductive material 110 is adjacent to the lining layer 104. For example, the center portion 110C of the top surface of the conductive material 110 has an angle θ1 that is between 90 degrees and 180 degrees. The peripheral portion 110P of the conductive material 110 has a sharp corner. In other words, an angle θ2 between the peripheral portion 110P and lining layer 140 is less than 90 degrees. The sharp corner of the peripheral portion 110P adjacent to the lining layer 104 may cause tip discharge, thereby causing the electrical properties of the word lines.

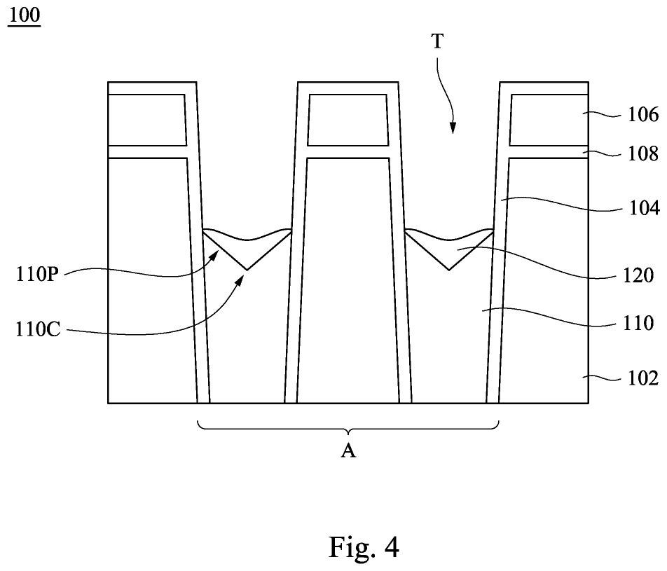

Referring to FIG. 4, a sacrificial film 120 is deposited on the top surface of the conductive material 110, wherein the sacrificial film 120 includes fluorine. In some embodiments, a precursor for forming the sacrificial film comprises nitrogen trifluoride (NF₃). In other embodiments, suitable fluorine-containing gases may be used as precursors for forming the sacrificial film 120. In some embodiments, the sacrificial film 120 includes titanium tetrafluoride (TiF₄). For example, fluorine in the precursor reacts with titanium in the bottom conductive material and produce TiFₓ. The sacrificial film 120 has a relatively flat top surface. In other words, the central recess of the conductive material 110 is filled. As shown in FIG. 4, the center portion the sacrificial film 120 is slightly lower than the peripheral portion of the sacrificial film 120. In other embodiments, the center portion the sacrificial film 120 is coplanar with the peripheral portion of the sacrificial film 120. In some embodiments, the thickness of peripheral portion of the sacrificial film 120 is less than the thickness of the center portion the sacrificial film 120. In other words, the thickness of the sacrificial film 120 located on the peripheral portion 110P of the conductive material 110 is less than the thickness of the sacrificial film 120 located on the center portion 110C of the conductive material 110.

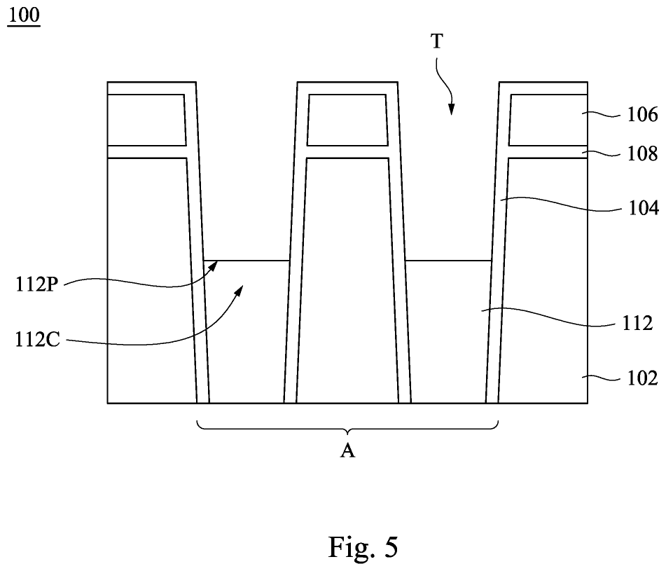

Referring to FIG. 5, a second etching process is performed to form a bottom conductive layer 112 in the trench T. In some embodiments, the first etching process is a gas etching process. In some embodiments, the first gas etchant includes fluorine and chlorine. In some embodiments, the first etching process is performed at a temperature of 115° C. to 120° C. Particularly, the peripheral portion 110P of the top surface of the conductive material 110 and the sacrificial film 120 are removed, such that a top surface of the bottom conductive layer 112 is a flat surface. For example, the sharp corner of the peripheral portion 110P of the conductive material 110 and the sacrificial film 120 are removed. In other words, a center portion 112C of a top surface of the bottom conductive layer 112 is coplanar with a peripheral portion 112P of the top surface of the bottom conductive layer 112. For example, the top surface of the bottom conductive layer 112 is parallel to the top surface of the substrate 102. Preferably, the sacrificial film 120 is completely removed in the second etching process.

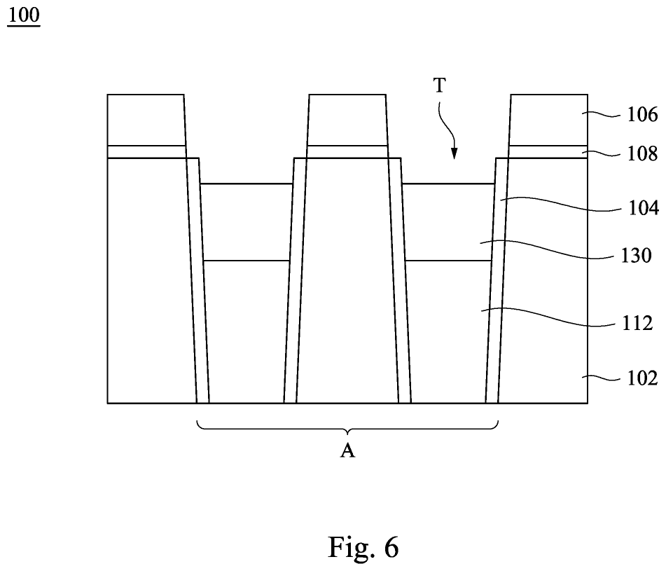

Referring to FIG. 6, a top conductive layer 130 is formed on the bottom conductive layer 112. In other words, the trench T is filled by the top conductive layer 130. For example, top conductive layer 130 is formed by chemical vapor deposition (CVD), atomic layer deposition (ALD), or physical vapor deposition (PVD). In some embodiments, top conductive layer 130 may include poly silicon. As the sharp corner is removed, the interface between the bottom conductive layer 112 and the top conductive layer 130 is relatively flat. Therefore, the problem of tip discharge of the semiconductor device can be reduced.

In some embodiments, a portion of the lining layer 104 that is located on the cover layer 106 is removed before forming the top conductive layer 130. In some embodiments, a portion of the lining layer 104 that is located on the cover layer 106 is removed after forming the top conductive layer 130.

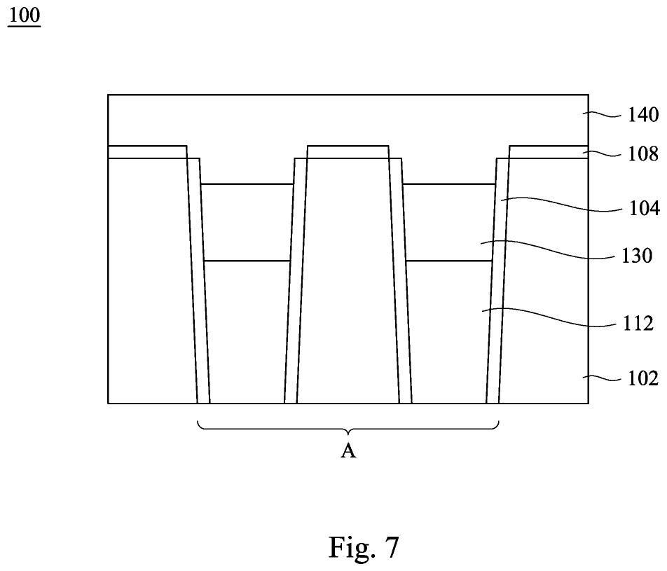

Referring to FIG. 7, a cap material is deposited to fill the trench T and above the substrate 102. In some embodiments, the cap material may be formed by any suitable deposition process such as chemical vapor deposition (CVD), atomic layer deposition (ALD), or physical vapor deposition (PVD). Next, a portion of the cap material is removed to form a capping layer 140 on the top conductive layer 130. In some embodiments, removing the portion of the cap material includes performing a planarization process, for example, a chemical mechanical planarization (CMP) process. In some embodiments, the capping layer 140 and the cover layer 106 include same material.

According to the above embodiments of the present disclosure, the present disclosure provides a manufacturing method of semiconductor device. With the method provided in the present disclosure, the V-shape surface of the bottom conductive layer can be improved. For example, the sharp corner of the bottom conductive layer is removed. Therefore, the problem of tip discharge of the semiconductor device can be reduced. This further improves the stability and yield of the semiconductor device.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A manufacturing method of semiconductor device, comprising:
providing a semiconductor structure, wherein the semiconductor structure comprises:
a substrate; and
a trench in the substrate;
depositing a conductive material to fill the trench;
performing a first etching process to etch back a portion the conductive material such that a top surface of the conductive material is a V-shape surface;
depositing a sacrificial film on the top surface of the conductive material, wherein the sacrificial film comprises fluorine;
performing a second etching process to form a bottom conductive layer in the trench, wherein the sacrificial film is removed such that a top surface of the bottom conductive layer is a flat surface; and
forming a top conductive layer on the bottom conductive layer.

2. The method of claim 1, wherein the semiconductor structure further comprises:
a lining layer disposed on a sidewall of the trench.

3. The method of claim 1, wherein a precursor for forming the sacrificial film comprises nitrogen trifluoride (NF₃).

4. The method of claim 1, wherein the sacrificial film comprises titanium tetrafluoride (TiF₄).

5. The method of claim 1, further comprising:
depositing a cap material to fill the trench and above the substrate; and
removing a portion of the cap material to form a capping layer on the top conductive layer.

6. The method of claim 5, wherein removing the portion of the cap material comprises performing a planarization process.

7. The method of claim 1, wherein the first etching process and the second etching process are gas etching process.

8. The method of claim 1, wherein an etchant used in the first etching process and the second etching process comprise chlorine.

9. The method of claim 1, wherein an etchant used in the first etching process and the second etching process comprise fluorine.

10. The method of claim 1, wherein the first etching process and the second etching process are performed at a temperature of 115° C. to 120° C.

11. The method of claim 1, wherein the conductive material is titanium nitride.

12. A manufacturing method of semiconductor device, comprising:
forming an active region in a substrate;
forming a trench in the active region;
depositing a lining layer in the trench;
depositing a conductive material to fill the trench;
performing a first etching process to etch back a portion of the conductive material such that a center portion of a top surface of the conductive material is lower than a peripheral portion of the top surface of the conductive material;
depositing a sacrificial film on the top surface of the conductive material, wherein the sacrificial film comprises fluorine;
performing a second etching process to form a bottom conductive layer in the trench, wherein the sacrificial film is removed such that a center portion of a top surface of the bottom conductive layer is coplanar with a peripheral portion of the top surface of the bottom conductive layer; and
forming a top conductive layer on the bottom conductive layer.

13. The method of claim 12, wherein a precursor for forming the sacrificial film comprises nitrogen trifluoride (NF₃).

14. The method of claim 12, wherein the sacrificial film comprises titanium tetrafluoride (TiF₄).

15. The method of claim 12, further comprising:
depositing a cap material to fill the trench and above the substrate; and
removing a portion of the cap material to form a capping layer on the top conductive layer.
